(19) United States
(12) Patent Application Publication
(10) Pub. No.: US 2016/0236445 A1
(43) Pub. Date: Aug. 18, 2016

(54) Composite Layer, Metal Layer and Anodized Layer

(71) Applicant: HEWLETT PACKARD DEVELOPMENT COMPANY, L.P., Houston, TX (US)

(72) Inventors: Yu-Chuan KANG, Taipei City (TW); Kuan-Ting WU, Taipei City (TW)

(21) Appl. No.: 15/024,846

(22) PCT Filed: Nov. 7, 2013
(86) PCT No.: PCT/US2013/068861

§ 371 Date: Mar. 24, 2016

(51) Int. Cl. B32B 15/14; B32B 15/20; G06F 1/16; B32B 38/00; H05K 5/00; B32B 5/02; B32B 37/18

(52) U.S. Cl. CPC B32B 15/14; B32B 5/024; B32B 15/20; B32B 37/18; B32B 38/0008; H05K 5/0017; G06F 1/1637; B32B 2255/06; B32B 2255/20; B32B 2262/0269; B32B 2262/101; B32B 2262/103; B32B 2262/105; B32B 2262/106; B32B 2307/584; B32B 2457/00; B32B 2311/00; B32B 2311/24; B32B 2315/02; B32B 2315/085; B32B 2313/04; B32B 2377/00

(57) ABSTRACT

A composite material may comprise a composite layer, a metal layer, and an anodized layer. In some cases, the composite layer may comprise a first metal and a fiber material. In some examples, the metal layer may comprise a second metal and be on the composite layer and the anodized layer may be on the metal layer.

### BACKGROUND

Composite materials are materials made from two or more constituent materials with different physical properties. When combined, the constituent materials produce a material with characteristics different from the individual components. For example, a light metal infiltrated carbon fiber composite, such as a carbon fiber metal matrix composite (MMC), may have carbon fibers embedded in a light metal matrix, such as aluminum, magnesium, or titanium. The resultant composite may have high strength and low density.

### BRIEF DESCRIPTION OF THE DRAWINGS

Certain examples are described in the following detailed description and in reference to the drawings, in which:

FIG. 1 illustrates an example composite material including a composite layer, a metal layer, and an anodized layer.

FIG. 2 illustrates an example composite material having two second metal layer and two anodized layers;

FIG. 3 illustrates an example method of manufacturing a composite material;

FIG. 4A illustrates an example electronic device having a housing comprising a composite material; and

FIG. 4B illustrates a magnified portion of the housing of FIG. 4A, illustrating the composite material,

### DETAILED DESCRIPTION OF SPECIFIC EXAMPLES

Users of consumer electronics, such as smartphones, laptops, and tablets, may desire electronics housings having certain qualities. For example, users may desire a housing that is scratch resistant, has a metallic feel, or that may be available in various colors. Anodized light metals, such as aluminum, magnesium, titanium, or their alloys, may provide such qualities. Anodizing is an electrolytic passivation process that forms an anodized metal layer on the surface of a metal by increasing the natural oxide layer of the metal. The resultant anodized layer may be harder than the underlying metal, providing a wear resistant coating that retains a metallic feel. Additionally, the anodized layer may be dyed various colors.

However, directly anodizing a light metal infiltrated carbon fiber composite material may provide an inferior anodized coating. In some cases, it may be difficult to achieve a consistent anodized layer thickness directly on a light metal infiltrated carbon fiber material. For example, the composite material may lack an anodized layer on exposed areas of carbon fiber, resulting in an irregular anodized layer structure. This may cause unsatisfactory texture and introduce color variation between different articles manufactured under the same processes.

Implementations of the disclosed technology may provide a composite material having an anodized coating on an infiltrated light metal carbon fiber composite substrate. The anodized coating may provide a high performance metallic finish with improved wear resistance and color uniformity. Such composite materials may be used in electronics, such as portable electronic products like notebook and tablet computers, and smartphones.

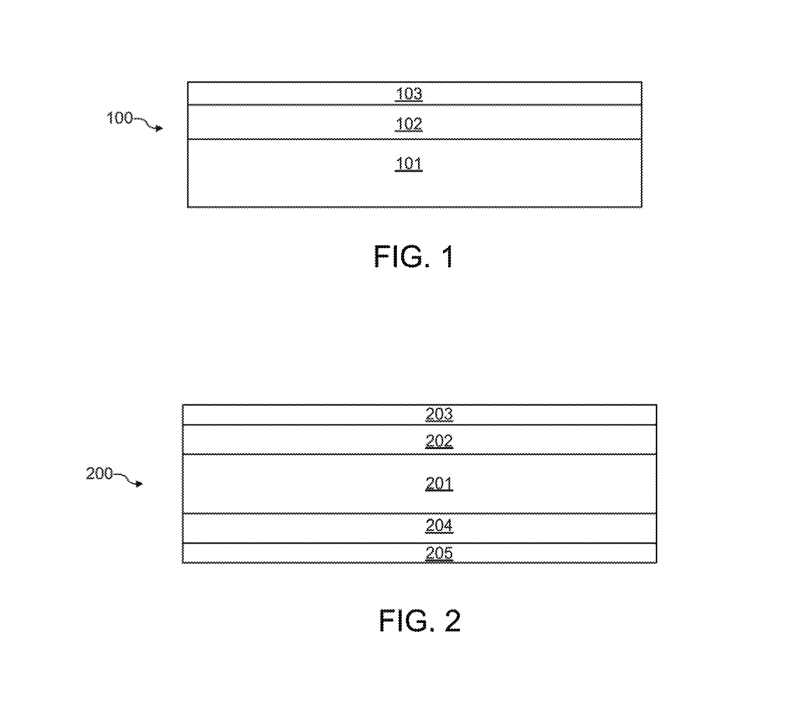

FIG. 1 illustrates an example composite material 100 including a composite layer 101, a metal layer 102, and an anodized layer 103. For example, the composite material 100 may be used in the construction of articles such as housing for electronics devices, such as laptops, tablets, smartphones, and peripherals.

The example composite material 100 includes a composite layer 101. In some implementations, the composite layer 101 may include a fiber material and a first metal infiltrating the fiber material. For example, the composite layer 101 may be a light metal infiltrated fiber material. The composite layer 101 may determine the bulk properties of the material 100, such as stiffness, plasticity, strength, and density. The composite layer 101 may have a variety of thicknesses depending on its application. For example, when used in the manufacture of a laptop housing, the composite layer 101 may have a thickness on the order of a few millimeters. For example, the composite layer 101 may have a thickness between 0.5-12 mm.

In some implementations, the first metal of composite layer 101 may be a light metal. In some cases, the light metal may comprise aluminum, aluminum alloys, magnesium, magnesium alloys, titanium, or titanium alloys. For example, the light metal may comprise magnesium alloyed with lithium and zinc (LZ), such as LZ91, or magnesium alloyed with aluminum and zinc (AZ), such as AZ31 or AZ91. As another example, the light metal may comprise pure aluminum, or aluminum alloyed with magnesium, such as a 5000 or 6000 series aluminum alloy.

In some implementations, the fiber material of composite layer 101 may comprise continuous or discontinuous fibers. For example, the fiber material may be a continuous, woven cloth. As another example, the fiber material may be in a discontinuous, unidirectional web. In various implementations, the fiber material of composite layer 101 may include carbon nanotubes, carbon fibers, glass fibers, ceramic fibers, silicon carbide fibers, aramid fibers, or metal fibers. Additionally, in some implementations, the fibers of composite layer 101 may be coated or uncoated. For example, the fiber material may be coated or uncoated carbon fibers, such as polyacrylonitrile-derived carbon fibers (PAN carbon fibers). In one implementation, the composite layer 101 may be an L2 alloy infiltrated woven PAN carbon fiber composite.

The composite material 100 may comprise a metal layer 102 on the composite layer 101. In some implementations, the metal layer 102 may comprise a second metal. In various implementations, the second metal of metal layer 102 may be the same as or different from the first metal of composite layer 101. In some cases, the second metal may be any metal capable of being anodized. For example, the metal layer 102 may include a light metal such as aluminum, aluminum alloy, magnesium, magnesium alloy, titanium, or titanium alloy. In some implementations, the metal layer 102 may be composed of aluminum or an aluminum alloy, such as a 5000 or 6000 series aluminum alloy. In other implementations, the metal layer 102 may be composed of magnesium or a magnesium alloy, such as LZ91, AZ31 or A291.In some implementations, the metal layer 102 may provide a metallic feel to the composite material 100 and may serve as a substrate for an anodized layer 103. In some cases, the metal layer 102 may have a thickness of greater than 50 μmm.

The example composite material 100 may comprise an anodized layer 103 on the metal layer 102. For example, the anodized layer 103 may be a layer composed of oxides of the second metal of metal layer 102. The anodized layer 103 may provide a harder surface than the metal layer 102 or the composite layer 101. Accordingly, a composite material 100 having an anodized layer 103 may be more scratch resistant than a composite material lacking such an anodized layer 103. Additionally, the anodized layer 103 may include a dye or colorant. In various implementations, the anodized layer 103 may have varying thickness depending on application. In some instances, the anodized layer 103 may be between 6 to 150 μm thick. The thickness may depend on the anodizing process and desired final characteristics. For example, a thin, transparent anodized layer 103 may produce iridescence effects, while a thicker anodized layer 103 may be used to retain dyes. In a particular implementation, the anodized layer 103 may be produced using a sulfuric acid anodizing process and have a thickness between 10 and 50 μm.

FIG. 2 illustrates an example composite material 200 having a second metal layer 204 and a second anodized layer 205. For example, composite material 200 may be used in applications where both surfaces of the material 200 will be visible. In this example, the composite material 200 has a first metal layer 202 on a composite layer 201. The composite material 200 further has a second metal layer 204 on a side of the composite layer 201 opposite the first layer 202. In this example, the composite material 200 may have a first anodized layer 203 on the first metal layer 202 and a second anodized layer 205 on the second metal layer 204.

In some implementations, the composite layer 201 has a composition similar to the composite layer 101 of FIG. 1. The composite layer 201 may include a fiber material and a first metal infiltrating the fiber material. For example, the composite layer 201 may be a light metal infiltrated fiber material. The composite layer 201 may determine the bulk properties of the material 200, such as stiffness, plasticity, strength, and density. The composite layer 201 may have a variety of thicknesses depending on its application. For example, when used in the manufacture of a laptop housing, the composite layer 201 may have a thickness on the order of a few millimeters. For example, the composite layer 201 may have a thickness between 0.5-12 mm.

In some implementations, the first metal of composite layer 201 may be a light metal. For example, the light metal may comprise aluminum, aluminum alloys, magnesium, magnesium alloys, titanium, or titanium alloys. For example, the light metal may comprise magnesium alloyed with lithium and zinc (LZ). such as LZ91, or magnesium alloyed with aluminum and zinc (AZ), such as AZ31 or AZ91. As another example, the light metal may comprise pure aluminum, or aluminum alloyed with magnesium, such as a 5000 or 6000 series aluminum alloy.

In some implementations, the fiber material of composite layer 201 may comprise continuous or discontinuous fibers. In various implementations, the fiber material of composite layer 201 may comprise carbon nanotubes, carbon fibers, glass fibers, ceramic fibers, silicon carbide fibers, aramid fibers, or metal fibers. Additionally, in some implementations, the fiber material of composite layer 201 may comprise coated or uncoated fibers. For example, the fiber material may comprise coated or uncoated carbon fibers, such as polyacrylonitrile-derived carbon fiber (PAN carbon fibers). In some implementations, the fiber material may be woven or unwoven. For example, the fiber material may be woven PAN carbon fiber. In some examples, the fiber material may be unwoven, unidirectional fibers. For example, the fiber material may be unidirectional PAN carbon fiber. In one implementation, the composite layer 201 may be an LZ alloy infiltrated woven PAN carbon fiber composite.

In some implementations, the first metal layer 202 and second metal layer 204 may have a composition similar to the metal layer 102 of FIG. 1. For example, the first metal layer 202 and second metal layer 204 may comprise second and third metals capable of being anodized. For example, the first metal layer 202 and second metal layer 204 may include light metals such as aluminum, aluminum alloy, magnesium, magnesium alloy, titanium, or titanium alloy. In some implementations, the first metal layer 202 and the second metal layer 204 are composed of aluminum or aluminum alloys, such as a 5000 or 6000 series aluminum alloy. In other implementations, the first metal layer 202 and the second metal layer 204 are composed of magnesium or magnesium alloys, such as LZ91, AZ31 or AZ91. In some implementations, the first metal layer 202 and the second metal layer 204 may provide a metallic feel to both surfaces of the composite material 200 and may serve as substrates for the first anodized layer 203 and the second anodized layer 205, respectively.

In some implementations, the first metal layer 202 may have a different composition than the second metal layer 204. For example, the first metal layer 202 may be composed of aluminum or an aluminum alloy while the second metal layer 204 may be composed of magnesium or a magnesium alloy. In other implementations, the first metal layer 202 and the second metal may have the same composition. Additionally, in some implementations, the first metal layer 202 may have a different thickness than the second metal layer 204. In other implementations, the first metal layer 202 and the second metal layer 204 have the same thickness. In some cases, the first metal layer 202 and the second metal layer 204 have thicknesses less than 2 mm.

The example composite material 200 may further include a first anodized layer 203 on the first metal layer 202 and a second anodized layer 205 on the second metal layer 204. In some implementations, the first anodized layer 203 may be a layer composed of oxides of the metal of the first metal layer 202. Similarly, the second anodized layer 205 may be a layer composed of oxides of the metal of the second metal layer 204. Additionally, the first anodized layer 203 and the second anodized layer 205 may include dyes or other colorants. In various implementations, the first anodized layer 203 and the second anodized layer 205 may have different thicknesses or may have the same thicknesses. Additionally, depending on the composition of the first metal layer 202 and the second metal layer 204, the first anodized layer 203 and the second anodized layer 205 may have different compositions or the same composition. Similarly, if dyed, the first anodized layer 203 and the second anodized layer 205 may be dyed different colors, or only one anodized layer 203, 205 may be dyed.

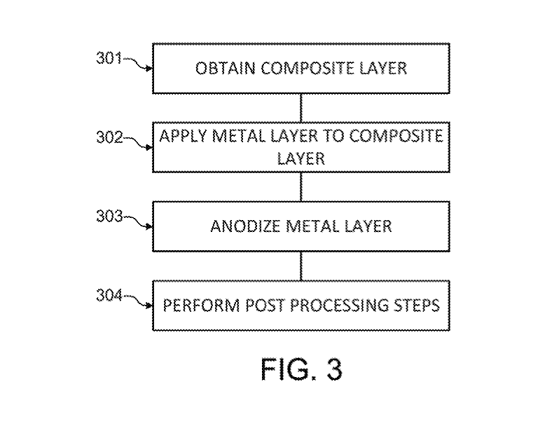

FIG. 3 illustrates an example method of manufacturing a composite material. For example, the illustrated method may be used to manufacture a composite material such as the composite material 100 described with respect to FIG. 1 or the composite material 200 described with respect to FIG. 2.

The example method may include block 301. Block 301 may include obtaining a composite layer comprising a fiber material and a first metal infiltrating the fiber material. For example, the composite layer may be similar to composite layer 101 of FIG. 1 or composite layer 201 of FIG. 2. In some implementations, the composite layer may be obtained in a pre-fabricated form. In other implementations, obtaining the composite layer may include forming the composite layer. For example, the composite layer may be formed by bonding a metal with a fiber material. In some cases, bonding the metal with the fiber material may include solid state methods such as powder blending and consolidation or foil diffusion bonding. In other cases, bonding the metal with the fiber material may include liquid state methods such as electroformlng, stir or squeeze casting, spray deposition, or reactive processing. In still further cases, bonding the metal with the fiber material may include physical vapor deposition methods, such as sputtering.

In some instances, the metal of the composite layer may include aluminum, an aluminum alloy, magnesium, a magnesium alloy, titanium, or a titanium alloy. Additionally, the fiber material may be continuous or discontinuous. For example, the fiber material may be in a continuous, woven form. In some implementations, the fiber material may be woven or unwoven. As another example, the fiber material may be in a discontinuous, unidirectional form. In various implementations, the fiber material may comprise carbon nanotubes, carbon fibers, glass fibers, ceramic fibers, silicon carbide fibers, aramid fibers, or metal fibers. Additionally, in some implementations, the fiber material may comprise coated or uncoated fibers. For example, the fiber material may comprise coated or uncoated carbon fibers, such as polyacrylonitrile-derived carbon fiber (PAN carbon fibers).

The example method may also include block 302. Block 302 may include applying a metal layer to the composite layer. For example, the metal layer may be as described with respect to metal layer 102 of FIG. 1 or metal layers 202, 204 of FIG. 2. In some implementations, applying the metal layer may include applying a metal foil to the composite layer and bonding the metal foil to the composite layer. For example, the metal foil may be bonded to the composite layer using diffusion bonding under heat and pressure. In other examples, the metal foil may be bonded to the composite layer through soldering, brazing, adhesive bonding, or other bonding techniques. In other implementations, applying the metal layer may include depositing the metal layer on the composite layer. For example, the metal layer may be deposited on the composite layer using a vapor deposition technique, such as physical vapor deposition.

In some implementations, block 302 may include applying a second metal layer to the composite layer on a side of the composite layer opposite the first metal layer. For example, the second metal layer may be as described with respect to metal layer 204 of FIG. 2. In some implementations, the second metal layer may be applied in the same manner as the first metal layer. For example, the second metal layer may be applied as a metal foil and bonded to the composite layer. In other implementations, the second metal layer may be applied in a different manner that the first metal layer. For example, the first metal layer may be applied as a metal foil bonded to the composite layer while the second layer may be applied through vapor deposition.

The example method may also include block 303. Block 303 may include anodizing the metal layer applied to the composite layer. For example, this may form an anodized layer as described with respect to anodized layer 103 of FIG. 1 or anodized layer 203 of FIG. 2. In some implementations, the metal layer is anodized by playing the bonded composite layer and metal layer into a chemical bath and passing an electric current through the bath, causing the surface of the metal layer to oxidize. In a particular implementation, the chemical bath may include sulfuric acid, chromic acid, caustic Soda, sodium nitrate, sodium nitrite, trisodium phosphate, orthophosporic acid, nitric acid, acetic acid glacial, silicic acid, boric acid, phosphoric acid, molybdic acid, vanadic acid, permanganic add, stannic acid and tungstic acid, nickel, and urea.

In some cases, by anodizing the metal layer after it is applied to the composite layer, the anodized layer is formed only on the external surface of the metal layer. Accordingly, an anodized layer may not be present at the interface between the metal layer and the composite layer.

In implementations where block 302 includes applying a second metal layer, block 303 may include anodizing the second metal layer applied to the composite layer. In some implementations, block 303 may include anodizing the second metal layer simultaneously with the first metal layer. For example, the first and second metal layers may be submerged into the same chemical acid bath during a single anodization process. In other implementations, block 303 may include anodizing the second metal layer separately from the first metal layer. In further embodiments, the second metal layer may not be anodized. For example, the second metal layer may be applied after the first metal layer is applied and anodized.

In some implementations, the example method may include block 304. Block 304 may include performing various post processing steps. For example, block 304 may include dying the anodized layer. If two layers are present, block 304 may include dying the first and second anodized layers, or only one of the anodized layers. As another example, block 304 may include sealing the anodized layer or layers. The sealing may reduce or eliminate pores in the anodized layer or layers. For example, sealing may include immersion in hot deionized water or steam, or impregnation with a sealant such as polytetrafluoroethylene (PTFE), nickel acetate, cobalt acetate, sodium dichromate, or potassium dichromate.

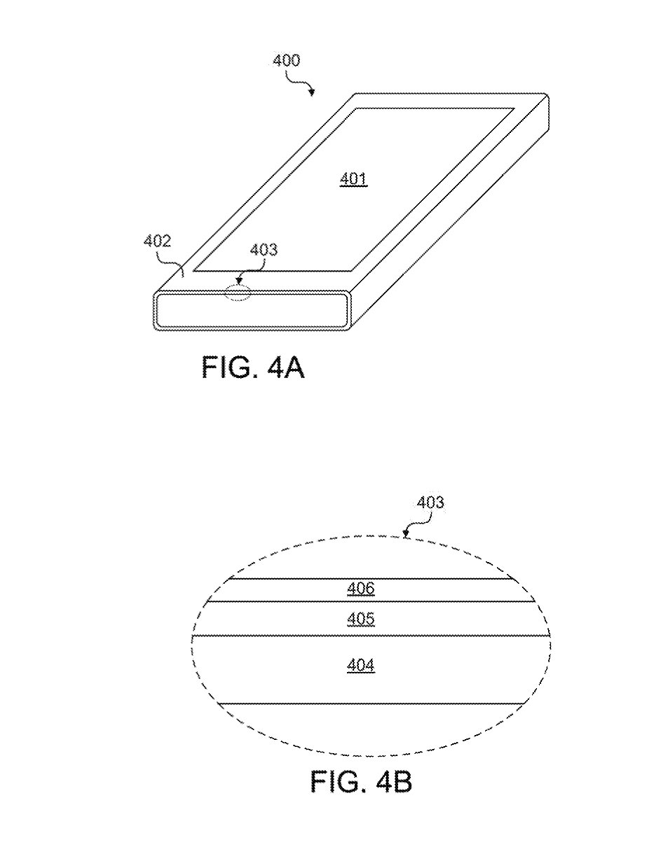

FIG. 4A illustrates an example electronic device 400 having a housing 402 comprising a composite material. FIG. 4B illustrates a magnified portion 403 of the housing 402, illustrating the composite material. The example device 400 may include a display 401 and a housing 402. In further examples, the device 400 may include further components, such as buttons, keyboards, speakers, cameras, ports or additional screens. For example, the electronic device 400 may be a smartphone, media player, tablet computer, laptop or notebook computer, or other portable device.

In this example, the housing 402 may comprise a metal-fiber composite layer 404. In some implementations, the metal-fiber composite layer 404 may be as described with respect to composite layer 101 of FIG. 1 or composite layer 201 of FIG. 2. For example, the metal-fiber composite layer 404 may have a metal matrix with an embedded fiber material. In some implementations, the metal matrix may comprise an aluminum, aluminum alloy, magnesium, magnesium, magnesium alloy, titanium, or titanium alloy matrix. In some implementations, the fiber material may comprise continuous or discontinuous carbon nanotubes, carbon fibers, glass fibers, ceramic fibers, silicon carbide fibers, aramid fibers, or metal fibers. Additionally, the fiber material may be in a woven or unidirectional form.

The housing 402 may further comprise a metal layer 405 bonded to the metal-fiber composite layer 404. In some implementations, the metal layer 405 may be as described with respect to metal layer 102 of FIG. 1. Additionally, in further implementations, the housing 402 may comprise a second metal layer bonded to the metal-fiber composite layer 404 on the opposite side of the metal fiber composite layer 404. In such implementations, the first metal layer 405 and the second metal layer may be as described with respect to metal layers 202 and 204 of FIG. 2. For example, the metal layer 405 or layers may comprise a layer 405 or layers of aluminum, aluminum alloy, magnesium, magnesium alloy, titanium, or titanium alloy. In particular implementations, the metal layer 405 may comprise a layer of aluminum or aluminum alloy.

The housing 402 may further comprise an anodized layer 406 formed on the metal layer 405. In some implementations, the anodized layer 406 may be as described with respect to anodized layer 103 of FIG. 1. Additionally, if a second metal layer is present, a second anodized layer may be formed on the second metal layer. In such an implementation, the first and second anodized layers may be as described with respect to anodized layers 203 and 205 of FIG. 2.

In the foregoing description, numerous details are set forth to provide an understanding of the subject disclosed herein. However, implementations may be practiced without some or all of these details. Other implementations may include modifications and variations from the details discussed above. It is intended that the appended claims cover such modifications and variations.

1. A composite material, comprising:
a composite layer comprising a fiber material and a first metal infiltrating the fiber material;
a metal layer on the composite layer, the metal layer comprising a second metal; and
an anodized layer on the metal layer.

2. The composite material of claim 1, wherein the first metal comprises aluminum, an aluminum alloy, magnesium, a magnesium alloy, titanium, or a titanium alloy.

3. The composite material of claim 1, wherein:
the fiber material comprises continuous or discontinuous carbon nanotubes, carbon fibers, glass fibers, ceramic fibers, silicon carbide fibers, aramid fibers, or metal fibers; and
the fiber material is in a woven or unidirectional form.

4. The composite material of claim 1, wherein the second metal comprises aluminum, aluminum alloy, magnesium, magnesium alloy, titanium, or titanium alloy.

5. The composite material of claim 1, wherein the metal layer has a thickness greater than or equal to 50 μm.

6. The composite material of claim 1, further comprising:
a second metal layer on a side of the composite layer opposite the first metal layer, the second metal layer comprising a third metal; and
a second anodized layer on the second metal layer.

7. A method, comprising:
obtaining a composite layer comprising a fiber material and a first metal infiltrating the fiber material;
applying a second metel the composite layer to form a metal layer; and
anodizing the metal layer applied to the composite layer.

8. The method of claim 7, comprising:
obtaining the composite layer by bonding aluminum, aluminum alloy, magnesium, magnesium alloy, titanium, or titanium alloy with the fiber material.

9. The method of claim 7, wherein:
the fiber material comprises continuous or discontinuous carbon nanotubes, carbon fibers, glass fibers, ceramic fibers, silicon carbide fibers, aramid fibers, or metal fibers; and
the fiber material is in a woven or unidirectional form.

10. The method of claim 7, comprising:
applying the metal layer by applying a foil to the composite layer and bonding the foil to the composite layer.

11. The method of claim 7, further comprising
applying a second metal layer to the composite layer on a side of the composite layer opposite the first metal layer; and
anodizing the second metal layer applied to the composite layer.

12. An electronic device, comprising:
a display; and
a housing comprising:
a metal-fiber composite layer comprising a fiber material and a metal matrix;
a metal layer bonded to the metal-fiber composite layer; and
an anodized layer formed on the metal layer.

13. The electronic device of claim 12, wherein:
the fiber material comprises continuous or discontinuous carbon nanotubes, carbon fibers, glass fibers, ceramic fibers, silicon carbide fibers, aramid fibers, or metal fibers; and
the fiber material is in a woven or unidirectional form.

14. The electronic device of claim 12, wherein the metal layer comprises a layer of aluminum, aluminum alloy, magnesium, magnesium alloy, titanium, or titanium alloy.

15. The electronic device of claim 14, wherein the metal layer comprises a layer of aluminum or aluminum alloy.
